(19) United States
(12) Patent Application Publication
(10) Pub. No.: US 2026/0304593 A1
(43) Pub. Date: Oct. 1, 2026

(54) ELECTRONIC DEVICE INCLUDING THERMAL INTERFACE MATERIAL

(71) Applicant: SAMSUNG ELECTRONICS CO., LTD., Suwon-si (KR)

(72) Inventors: Sunghyun RYU, Suwon-si (KR); Kihwan KWON, Suwon-si (KR); Jaeyoung HUH, Suwon-si (KR); Wooyoung JEONG, Suwon-si (KR); Hyeongsoon PARK, Suwon-si (KR)

(73) Assignee: SAMSUNG ELECTRONICS CO., LTD., Suwon-si (KR)

(21) Appl. No.: 19/459,697

(22) Filed: Jan. 26, 2026

Related U.S. Application Data
(63) Continuation of application No. PCT/KR2025/023245, filed on Dec. 31, 2025.

(30) Foreign Application Priority Data
Mar. 31, 2025 (KR) 10-2025-0041738
Jun. 2, 2025 (KR) 10-2025-0072339
Jun. 27, 2025 (KR) 10-2025-0086075

(51) Int. Cl. H05K 1/02; H05K 1/181

(52) U.S. Cl. CPC H05K 1/0203; H05K 1/181; H05K 2201/10734

(57) ABSTRACT

An electronic device including: a printed circuit board; a first package including first circuitry and disposed on the printed circuit board; a second package including second circuitry and disposed on the first package, wherein the first package includes a first portion on which the second package is disposed and a second portion; a first thermal interface material (TIM) disposed on the second portion of the first package; a second TIM disposed on the second package and the first TIM; and a heat dissipation member thermally connected to the first package and the second package through the first TIM and the second TIM, wherein the first TIM has a stiffness greater than that of the second TIM.

### CROSS-REFERENCE TO RELATED APPLICATIONS

This application is a continuation application, claiming priority under 35 U.S.C. § 365(c), of an International application No. PCT/KR2025/023245, filed on Dec. 31, 2025, which is based on and claims the benefit of a Korean patent application number 10-2025-0041738, filed on Mar. 31, 2025, in the Ministry of Intellectual Property, of a Korean patent application number 10-2025-0072339, filed on Jun. 02, 2025, in the Ministry of Intellectual Property, and of a Korean patent application number 10-2025-0086075, filed on Jun. 27, 2025, in the Ministry of Intellectual Property, the disclosure of each of which is incorporated by reference herein in its entirety.

### BACKGROUND

### 1. Field

The present disclosure relates to an electronic device including a thermal interface material.

### 2. Description of Related Art

An electronic device may include electronic components for providing various functions. The electronic components may include a component that generates heat when operating. In order to reduce function deterioration of the electronic device due to heat generated from the component, the electronic device may include a thermal interface material (TIM) thermally connecting the component to another member (e.g., a heat dissipation member or a heat sink).

The above-described information may be provided as a related art for the purpose of helping understanding of the present disclosure. No argument or decision is made as to whether any of the above description may be applied as a prior art related to the present disclosure.

### SUMMARY

One or more embodiments of the present disclosure may provide an electronic device comprising: a printed circuit board; a first package including first circuitry and disposed on the printed circuit board; a second package including second circuitry and disposed on the first package, wherein the first package includes a first portion on which the second package is disposed and a second portion; a first thermal interface material (TIM) disposed on the second portion of the first package; a second TIM disposed on the second package and the first TIM; and a heat dissipation member thermally connected to the first package and the second package through the first TIM and the second TIM, wherein the first TIM has a stiffness greater than that of the second TIM..

One or more embodiments of the present disclosure may provide an electronic device comprising: a printed circuit board; a first package on the printed circuit board and including first circuitry and disposed on the printed circuit board; a second package on the first package and including second circuitry and disposed on the first package, wherein the first package includes a first portion and a second portion, the second package being on the first portion on which the second package is disposed and a second portion not covered by the second package; a shield can disposed on the printed circuit board around the first package and the second packages and having an opening in a top wall thereof corresponding the second package; a shielding sheet disposed on the shield can and over the opening; a first thermal interface material (TIM) disposed on the second portion of the first package and thermally connected with to the first package; a second TIM disposed on the second package and the first TIM and under the shielding sheet, the second TIM being thermally connected with to the first TIM, the second package, and the shielding sheet; and a heat dissipation member disposed on the shielding sheet and thermally connected to the shielding sheet, wherein the first TIM has a first stiffness greater than that a second stiffness of the second TIM..

### BRIEF DESCRIPTION OF DRAWINGS

FIG. 1 is a block diagram of an electronic device in a network environment according to one or more embodiments.

FIG. 2A is a diagram indicating an electronic device.

FIG. 2B is an exploded perspective view of an electronic device.

FIG. 3 is a plan view indicating a printed circuit board of an electronic device and components disposed therein.

FIG. 4 is a diagram indicating a printed circuit board and packages disposed therein.

FIG. 5 is a plan view indicating a first package disposed on a printed circuit board and a non-conductive material applied to the first package.

FIG. 6 is a cross-sectional view indicating a heat transfer structure (or a heat dissipation structure) of an electronic device.

FIG. 7 is a plan view, a back surface view, and a side view indicating a first thermal interface material (TIM) and a second TIM.

FIG. 8 is a side view indicating packages and TIMs.

FIG. 9 is a cross-sectional view indicating a heat transfer structure (or a heat dissipation structure) of an electronic device.

FIG. 10 is a plan view, a back surface view, and a side view indicating a first TIM and a second TIM.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, “about the same”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

Unless otherwise indicated, as used herein with regard to any plurality of a particular type of component, any two components of that type are considered “adjacent” or “adjacent to” one another so long as no other component of that type occupies a space between the two components. That is, the two components are considered adjacent each other if the two components are not separated from each other by an intervening component of that type.

Furthermore, although one or more embodiments may comprise the disclosed features as described herein—as well as additional features not specifically described—other embodiments may instead be completely free of non-disclosed elements. For example, non-disclosed elements may be completely omitted from one or more embodiments of the present disclosure.

As used herein, the terms “front (or forward)”, “rear (or back, backward, rearward)”, “up (or upper, top, above)”, “down (or lower, bottom, below)”, “left”, “right”, and the like may be defined with reference to the drawings, and may not be intended to limit the shape and/or position of each component.

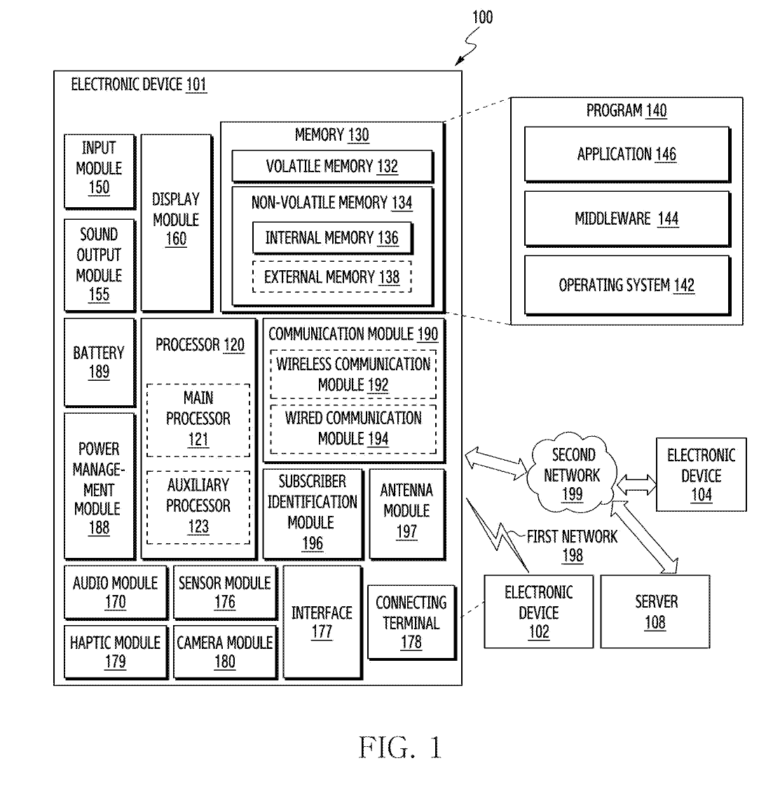

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module(SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly, or “hardwired”) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

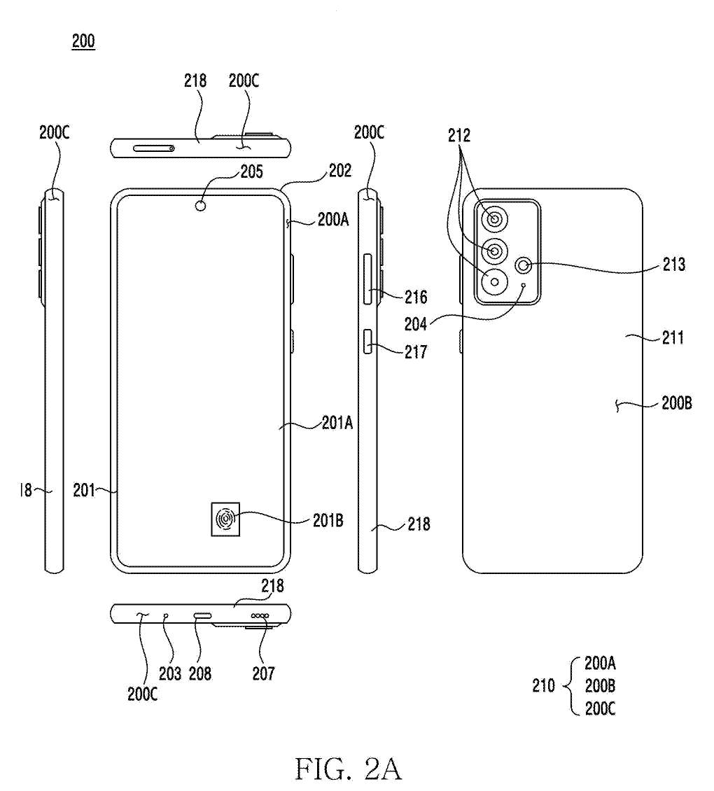

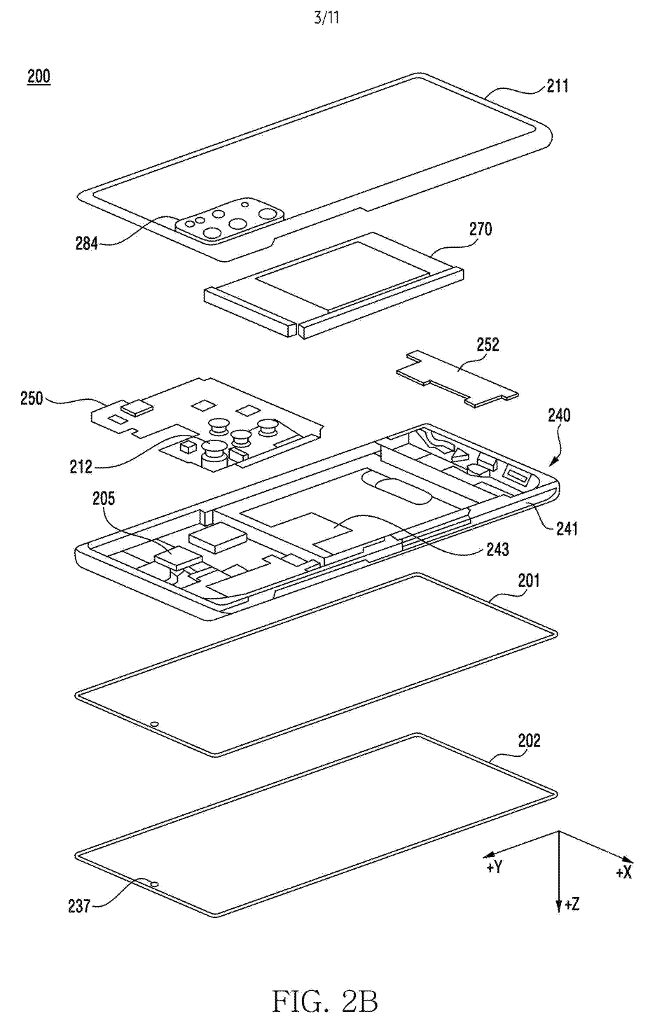

FIG. 2A is a diagram indicating an electronic device.

Referring to FIG. 2A, according to an embodiment, an electronic device 200 may include a housing 210 at least partially forming an exterior of the electronic device 200. For example, the housing 210 may include a first surface (or a front surface) 200A, a second surface (or a rear surface) 200B, and a third surface (or a side surface) 200C surrounding a space between the first surface 200A and the second surface 200B. In an embodiment, the housing 210 may refer to a structure forming at least a portion of the first surface 200A, the second surface 200B, and/or the third surface 200C.

According to an embodiment, the electronic device 200 may include a substantially transparent front plate 202. In an embodiment, the front plate 202 may form at least a portion of the first surface 200A. In an embodiment, the front plate 202, for example, may include a glass plate or a polymer plate including various coating layers, but is not limited thereto.

According to an embodiment, the electronic device 200 may include a substantially opaque rear plate 211. In an embodiment, the rear plate 211 may form at least a portion of the second surface 200B. In an embodiment, the rear plate 211 may be formed of coated or colored glass, ceramic, polymer, metal (e.g., aluminum, stainless steel, or magnesium), or a combination of at least two of the materials.

According to an embodiment, the electronic device 200 may include a side bezel structure (e.g., a side surface member or a bracket) 218. In an embodiment, the side bezel structure 218 may form at least a portion of the third surface 200C of the electronic device 200 by being coupled to the front plate 202 and/or the rear plate 211. For example, the side bezel structure 218 may form the entire third surface 200C of the electronic device 200, and for another example, the side bezel structure 218 may form the third surface 200C of the electronic device 200 together with the front plate 202 and/or the rear plate 211.

Unlike an illustrated example, in case that the third surface 200C of the electronic device 200 is partially formed by the front plate 202 and/or the rear plate 211, the front plate 202 and/or the rear plate 211 may include a portion extending by being bent toward the rear plate 211 and/or the front plate 202 at its periphery. For example, the extending portion of the front plate 202 and/or the rear plate 211 may be positioned at both ends of a long edge of the electronic device 200, but is not limited by the above-described example.

In an embodiment, the side bezel structure 218 may include metal and/or a polymer. In an embodiment, the rear plate 211 and the side bezel structure 218 may be integrally formed, and may include the same material (e.g., a metal material such as aluminum), but are not limited thereto. For example, the rear plate 211 and the side bezel structure 218 may be formed in a separate configuration and/or may include different materials.

In an embodiment, the electronic device 200 may include a display 201 (e.g., the display module 160 of FIG. 1), an audio module 203, 204, or 207 (e.g., the audio module 170 of FIG. 1), a sensor module (e.g., the sensor module 176 of FIG. 1), a camera module 205, 212, or 213 (e.g., the camera module 180 of FIG. 1), a light emitting element (not illustrated), and a connector hole 208. In an embodiment, the electronic device 200 may omit at least one (e.g., the light emitting element (not illustrated)) of the components, or may additionally include another component.

In an embodiment, the display 201 may be visually exposed through a large portion of the front plate 202. For example, at least a portion of the display 201 may be visible through the front plate 202 forming the first surface 200A. The display 201 may be disposed on a back surface of the front plate 202.

In an embodiment, an outer shape of the display 201 may be formed generally the same as an outer shape of the front plate 202 adjacent to the display 201 to expand an area in which the display 201 is visually exposed. In an embodiment, a distance between an outer periphery of the display 201 and an outer periphery of the front plate 202 may be formed generally the same.

In an embodiment, the display 201 (or the first surface 200A of the electronic device 200) may include a screen display region 201A. In an embodiment, the display 201 may provide visual information to a user through the screen display region 201A. In the illustrated embodiment, when the first surface 200A is viewed frontally, the screen display region 201A is illustrated to be spaced apart from an outer periphery of the first surface 200A and positioned inside the first surface 200A, but is not limited thereto. For example, when the first surface 200A is viewed frontally, at least a portion of a periphery of the screen display region 201A may also substantially coincide with a periphery of the first surface 200A (or the front plate 202).

In an embodiment, the screen display region 201A may include a sensing region 201B configured to obtain biometric information of the user. Herein, the meaning of “the screen display region 201A includes the sensing region 201B” may be understood as that at least a portion of the sensing region 201B may be overlapped on the screen display region 201A. For example, the sensing region 201B, like another region of the screen display region 201A, may mean a region capable of displaying visual information by the display 201 and additionally obtaining the biometric information (e.g., a fingerprint) of the user. Although it is illustrated that the sensing region 201B is formed in the screen display region 201A, it is not limited thereto. For example, the sensing region 201B may be formed in a key input device 216 and/or a key input device 217.

In an embodiment, the display 201 may include a region in which a first camera module 205 is positioned. For example, an opening may be formed in the region of the display 201, and the first camera module 205 (e.g., a punch hole camera) may be at least partially disposed in the opening to face the first surface 200A. In this case, the screen display region 201A may surround at least a portion of a periphery of the opening. In an embodiment, the first camera module 205 (e.g., an under display camera (UDC)) may be disposed under the display 201 to overlap with the region of the display 201. In this case, the display 201 may provide the visual information to the user through the region, and additionally, the first camera module 205 may obtain an image corresponding to a direction toward the first surface 200A through the region of the display 201.

In an embodiment, the display 201 may be coupled with or disposed adjacent to touch sensing circuitry, a pressure sensor capable of measuring a strength (pressure) of a touch, and/or a digitizer that detects a magnetic field-type stylus pen.

In an embodiment, the audio module 203, 204, or 207 may include a microphone hole 203 or 204 and a speaker hole 207.

In an embodiment, the microphone hole 203 or 204 may include a first microphone hole 203 formed in a partial region of the third surface 200C and a second microphone hole 204 formed in a partial region of the second surface 200B. A microphone for obtaining an external sound may be disposed inside the microphone hole 203 or 204. The microphone may include a plurality of microphones to detect a direction of a sound, but it is not limited thereto.

In an embodiment, the second microphone hole 204 formed in the partial region of the second surface 200B may be disposed adjacent to the camera module 205, 212, or 213. For example, the second microphone hole 204 may obtain a sound according to an operation of the camera module 205, 212, or 213. However, it is not limited thereto.

In an embodiment, the speaker hole 207 may include an external speaker hole 207 and a receiver hole for a call (not illustrated). The external speaker hole 207 may be formed on a portion of the third surface 200C of the electronic device 200. In an embodiment, the external speaker hole 207 may be integrated into the microphone hole 203, and the speaker hole 207 and the microphone hole 203 may be implemented as a hole. Although not illustrated, the receiver hole for a call (not illustrated) may be formed on another portion of the third surface 200C. For example, the receiver hole for a call may be formed on an opposite side of the external speaker hole 207 on the third surface 200C. For example, based on illustration of FIG. 2A, the external speaker hole 207 may be formed on the third surface 200C corresponding to a bottom side of the electronic device 200, and the receiver hole for a call may be formed on the third surface 200C corresponding to a top side of the electronic device 200. However, it is not limited thereto, and in another embodiment, the receiver hole for a call may also be formed at a position other than the third surface 200C. For example, the receiver hole for a call may also be formed by a separated space between the front plate 202 (or the display 201) and the side bezel structure 218.

In an embodiment, the electronic device 200 may include at least one speaker (not illustrated) (e.g., the sound output module 155 of FIG. 1) configured to output a sound to an outside of the housing 210 through the external speaker hole 207 and/or the receiver hole for a call (not illustrated).

In an embodiment, the sensor module (not illustrated) may generate an electrical signal or a data value corresponding to an internal operating state or an external environmental state of the electronic device 200. For example, the sensor module may include at least one of a proximity sensor, an HRM sensor, a fingerprint sensor, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

In an embodiment, the camera modules 205, 212, or 213 may include a first camera module 205 disposed to face the first surface 200A of the electronic device 200, a second camera module 212 disposed to face the second surface 200B of the electronic device 200, and a flash 213.

In an embodiment, the second camera module 212 may include a plurality of cameras (e.g., a dual camera, a triple camera, or a quad camera). However, the second camera module 212 is not necessarily limited to including the plurality of cameras, and may also include a camera.

In an embodiment, the first camera module 205 and the second camera module 212 may include one or a plurality of lenses, an image sensor, and/or an image signal processor.

In an embodiment, the flash 213 may include, for example, a light emitting diode or a xenon lamp. In an embodiment, two or more lenses (an infrared camera, wide-angle and telephoto lens) and image sensors may be disposed on a surface of the electronic device 200.

In an embodiment, the electronic device 200 may include one or more key buttons for receiving a user input. For example, the electronic device 200 may include key buttons 216 and 217 disposed in the housing 210 to form a portion (e.g., a portion of the third surface 200C) of an exterior of the electronic device 200.

In an embodiment, the connector hole 208 may be formed on the third surface 200C of the electronic device 200 so that a connector of an external device may be accommodated. A connection terminal (e.g., the connection terminal 178 of FIG. 1) electrically connected to the connector of the external device may be disposed in the connector hole 208. According to an embodiment, the electronic device 200 may include an interface module (e.g., the interface 177 of FIG. 1) for processing an electrical signal transmitted and received through the connection terminal.

In an embodiment, the electronic device 200 may include the light emitting element (not illustrated). For example, the light emitting element (not illustrated) may be disposed on the first surface 200A of the housing 210. The light emitting element (not illustrated) may provide state information of the electronic device 200 in an optical form. In an embodiment, the light emitting element (not illustrated) may provide a light source linked with an operation of the first camera module 205. For example, the light emitting element (not illustrated) may include an LED, an IR LED, and/or the xenon lamp.

FIG. 2B is an exploded perspective view of an electronic device.

Referring to FIG. 2B, according to an embodiment, an electronic device 200 may include a frame structure 240 (e.g., the side bezel structure 218 of FIG. 2A), a first printed circuit board 250, a second printed circuit board 252, and a battery 270 (e.g., the battery 189 of FIG. 1).

In an embodiment, the frame structure 240 may be positioned between the display 201 and the rear plate 211. In an embodiment, the frame structure 240 may support or accommodate components included in the electronic device 200. For example, the display 201 may be disposed on a surface of the frame structure 240 facing in a direction (e.g., a +z direction). The first printed circuit board 250, the second printed circuit board 252, the battery 270, and the second camera module 212 may be disposed on another surface facing a direction (e.g., a -z direction) opposite to the direction of the frame structure 240. The first printed circuit board 250, the second printed circuit board 252, the battery 270, and the second camera module 212 may be disposed in a recess formed in the frame structure 240.

In an embodiment, the frame structure 240 may include a first part 241 and a second part 243. An ambient portion of the second part 243 may be surrounded by the first part 241. The first part 241 may surround a space between the rear plate 211 and the front plate 202 (and/or the display 201). The first part 241 surrounding the space may at least partially form a side surface (e.g., the third surface 200C of FIG. 2A) of the electronic device 200, and the second part 243 positioned in the space may extend inwardly from the first part 241. The second part 243 may be positioned under (e.g., a -z direction) the display 201. In an embodiment, the first part 241 and/or the second part 243 may be formed of metal and/or a polymer.

The frame structure 240 (or the first part 241 of the frame structure 240) may be referred to as a side member or a lateral structure in that it forms the side surface of the electronic device 200. For example, the first part 241 of the frame structure 240 may be referred to as a side wall or a side wall portion of the housing 210 of the electronic device 200.

The frame structure 240 (or the second part 243 of the frame structure 240) may be referred to as a support member, a support structure, or a bracket in terms of supporting various components of the electronic device 200. For example, the second part 243 of the frame structure 240 may be referred to as a bracket, a bracket portion, and a support portion of the housing 210 of the electronic device 200.

In an embodiment, the first printed circuit board 250, the second printed circuit board 252, and the battery 270 may be coupled to the frame structure 240, respectively. For example, the first printed circuit board 250 and the second printed circuit board 252 may be fixedly disposed in the frame structure 240 through a coupling member such as a screw. For example, the battery 270 may be fixedly disposed in the frame structure 240 through an adhesive member (e.g., a double-sided tape). However, it is not limited by the above-described example.

In an embodiment, the display 201 may be disposed between the frame structure 240 and the front plate 202. For example, the front plate 202 may be disposed on a side (e.g., a +z direction) of the display 201, and the frame structure 240 may be disposed on another side (e.g., a -z direction).

In an embodiment, the front plate 202 may be coupled to the display 201. For example, the display 201 may be attached to a back surface of the front plate 202 through an optical adhesive member (e.g., optically clear adhesive (OCA) or optically clear resin (OCR)).

In an embodiment, the front plate 202 may be coupled to the frame structure 240. For example, the front plate 202 may include an outer portion extending outside the display 201 when viewed in the z-axis direction. The outer portion of the front plate 202 may be coupled to the frame structure 240 (e.g., the first part 241).

In an embodiment, a processor (e.g., the processor 120 of FIG. 1), memory (e.g., the memory 130 of FIG. 1), and/or an interface (e.g., the interface 177 of FIG. 1) may be disposed in the first printed circuit board 250 and/or the second printed circuit board 252. For example, the processor may include one or more of a central processing unit, an application processor, a graphics processing unit, an image signal processor, a sensor hub processor, or a communication processor. For example, the memory may include volatile memory or non-volatile memory. For example, the interface may include a high definition multimedia interface (HDMI), a universal serial bus (USB) interface, an SD card interface, and/or an audio interface. The interface may electrically or physically connect the electronic device 200 to an external electronic device, and may include a USB connector, an SD card/MMC connector, or an audio connector. In an embodiment, the first printed circuit board 250 and the second printed circuit board 252 may be operatively or electrically connected to each other through a connecting member (e.g., a flexible printed circuit board).

In an embodiment, the battery 270 may supply power to at least one component of the electronic device 200. For example, the battery 270 may include a rechargeable secondary battery or a fuel cell.

In an embodiment, the first camera module 205 (e.g., a front camera) may be disposed at least a portion (e.g., the second part 243) of the frame structure 240 so that a lens may receive external light through a partial region (e.g., a camera region 237) of the front plate 202 (e.g., the front surface 200A of FIG. 2A).

In an embodiment, the second camera module 212 (e.g., a rear camera) may be disposed between the frame structure 240 and the rear plate 211. In an embodiment, the second camera module 212 may be electrically connected to the first printed circuit board 250 through a connecting member (e.g., a connector). In an embodiment, the second camera module 212 may be disposed so that a lens may receive external light through a camera region 284 of the rear plate 211 of the electronic device 200.

In an embodiment, the camera region 284 may be formed on an outer surface (e.g., the rear surface 200B of FIG. 2A) of the rear plate 211. In an embodiment, the camera region 284 may be at least partially transparently formed so that the external light may be incident on the lens of the second camera module 212. In an embodiment, at least a portion of the camera region 284 may protrude from the outer surface of the rear plate 211 to a predetermined height. However, it is not limited thereto, and in another embodiment, the camera region 284 may form substantially the same plane as the outer surface of the rear plate 211.

In an embodiment, the housing 210 of the electronic device 200 may mean a configuration or a structure forming at least a portion of the exterior of the electronic device 200. In this respect, at least a portion of the front plate 202, the frame structure 240, and/or the rear plate 211 forming the exterior of the electronic device 200 may be referred to as the housing 210 of the electronic device 200.

Although the bar-type electronic device 200 is exemplified in FIGS. 2A and 2B, the shape or form factor of the electronic device 200 is not limited by the illustrated example.

For example, a housing of the electronic device 200 may be configured to be deformable. For example, the electronic device 200 may further include a second housing movably coupled to the housing 210 (or the first housing 210). For example, the second housing may be configured to be rotatable with respect to the first housing 210 through a hinge mechanism (or a hinge structure). The first housing 210 and the second housing may be folded or unfolded by a rotation operation of the second housing with respect to the first housing 210. In this case, the display 201 of the electronic device 200 may be disposed across the housing 210 and the other housing (e.g., across the hinge structure). In addition, the display 201 of the electronic device 200 may include a flexible display configured to be deformed according to a folding operation of the housing 210 and the other housing.

Additionally, the electronic device 200 may further include a third housing movably coupled to the first housing 210 or the second housing. For example, the third housing may be rotatably coupled to the first housing 210 (e.g., on the opposite side of the second housing) through the hinge mechanism (or the hinge structure). For another example, the third housing may be rotatably coupled to the second housing through the hinge mechanism (or the hinge structure). As described above, the electronic device 200 including a plurality of housings movably coupled to each other may be referred to as a foldable electronic device or a multi-foldable electronic device.

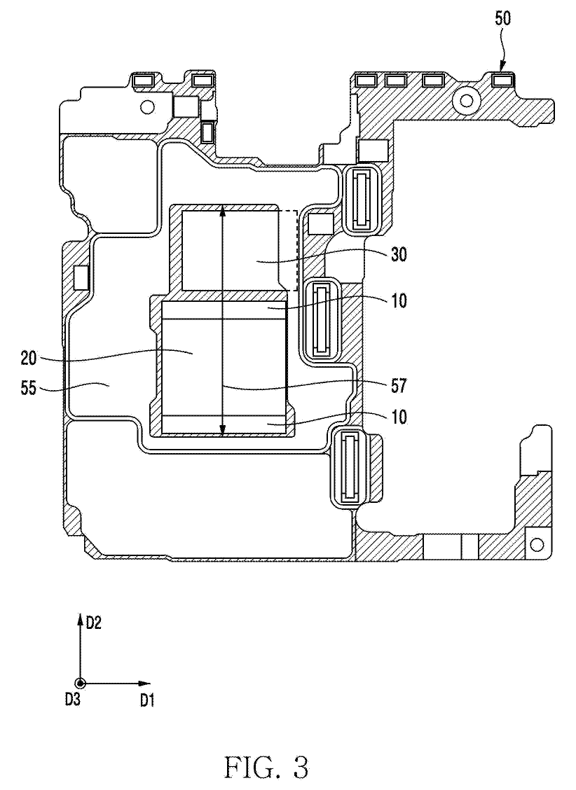

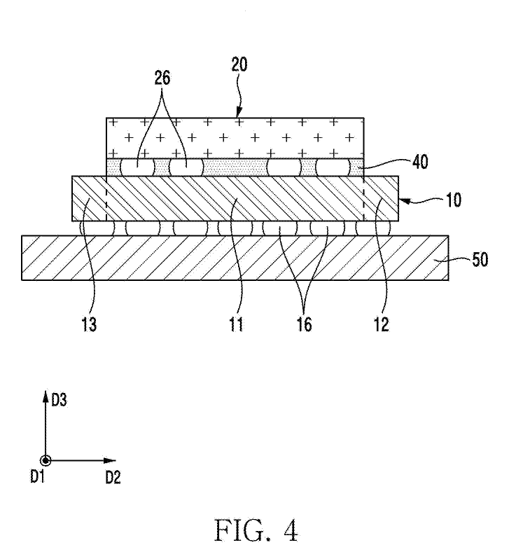

FIG. 3 is a plan view indicating a printed circuit board of an electronic device and components disposed therein. FIG. 4 is a diagram indicating a printed circuit board and packages disposed therein.

In the present disclosure, directions D1, D2, and D3 orthogonal to each other are defined. A second direction D2 may be a direction perpendicular to a first direction D1, and a third direction D3 may be a direction perpendicular to both the first direction D1 and the second direction D2. The third direction D3 may be a direction substantially perpendicular to a printed circuit board 50. For example, the first direction D1 may be a +X direction of FIG. 2B, but is not limited thereto. For example, the second direction D2 may be a +Y direction of FIG. 2B, but is not limited thereto. For example, the third direction D3 may be a +Z direction of FIG. 2B, but is not limited thereto.

Referring to FIG. 3, according to an embodiment, an electronic device (e.g., an electronic device 200) may include the printed circuit board 50 (e.g., a first printed circuit board 250), a shield can 55, a first package 10, a second package 20, and a third package 30.

The first package 10 and the second package 20 may be disposed on the printed circuit board 50, respectively. For example, the first package 10 may be disposed on a surface of the printed circuit board 50 facing the third direction D3. The second package 20 may be disposed on the first package 10. For example, the second package 20 may be disposed on a surface of the first package 10 facing the third direction D3.

The shield can 55 may be disposed on the printed circuit board 50. The shield can 55 may be disposed on the surface of the printed circuit board 50 facing the third direction D3. For example, the shield can 55 may be disposed on the printed circuit board 50 to surround the packages 10, 20, and 30. For example, the shield can 55 may include a side wall disposed on the printed circuit board 50 and substantially perpendicular to the printed circuit board 50, and a top wall extending from the side wall. The side wall of the shield can 55 may surround the side surfaces of the packages 10, 20, and 30.

The shield can 55 may include a top opening 57. The top opening 57 may be formed in the top wall of the shield can 55. The top opening 57 may overlap (e.g., in the third direction D3) at least a portion of the first package 10. For example, when the printed circuit board 50 is viewed from above, a region in which the top opening 57 is projected may overlap the at least a portion of the first package 10. In addition, the top opening 57 may overlap at least a portion of the second package 20. For example, when the printed circuit board 50 is viewed from above, a region in which the top opening 57 is projected may overlap the at least a portion of the second package 20. In FIG. 3, all of the first package 10 and all of the second package 20 were illustrated to overlap the top opening 57 of the shield can 55, but the present disclosure is not limited thereto.

The top opening 57 may overlap (e.g., in the third direction D3) at least a portion of the third package 30. For example, when the printed circuit board 50 is viewed from above, a region in which the top opening 57 is projected may overlap the at least a portion of the third package 30. In FIG. 3, it is illustrated that the portion of the third package 30 is covered by the top wall of the shield can 55, and another portion (e.g., the remaining portion) of the third package 30 overlaps the top opening 57 of the shield can 55, but the present disclosure is not limited thereto.

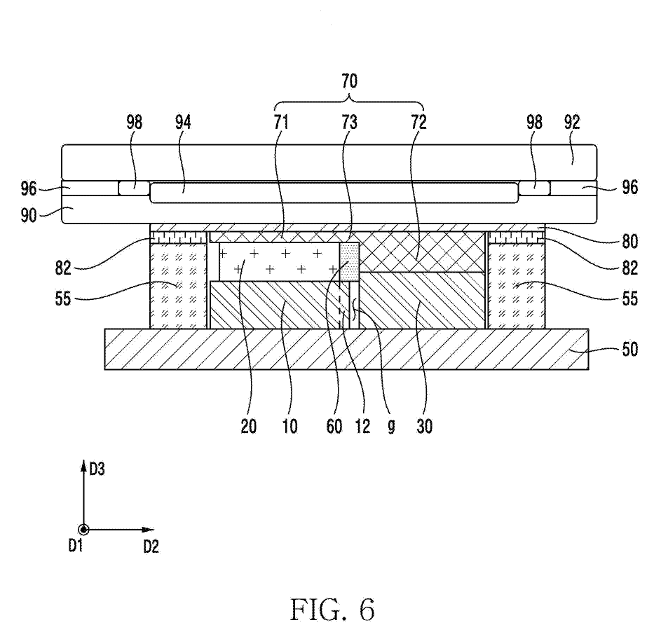

The shield can 55 may be configured to provide electromagnetic shielding. For example, the shield can 55 may include a layer formed of a conductive material (e.g., metal) or formed therefrom. For example, the shield can 55 may provide electromagnetic shielding for the first package 10, the second package 20, and the third package 30 disposed therein. Since the shield can 55 has the top opening 57, the electronic device may further include a shielding sheet (e.g., a first sheet 80 of FIG. 6) attached to the top wall of the shield can 55 to cover the top opening 57 to provide stable shielding for the first package 10, the second package 20, and the third package 30. Alternatively, the top opening 57 may not be formed in the top wall of the shield can 55.

Referring to FIGS. 3 and 4, the first package 10 may be disposed on the printed circuit board 50. For example, the first package 10 may be positioned on the printed circuit board 50 through a plurality of solder balls 16. The plurality of solder balls 16 may be described as being included in the printed circuit board 50 and/or the first package 10.

The second package 20 may be disposed on the first package 10. For example, the second package 20 may be positioned on the first package 10. For example, the second package 20 may be positioned on the first package 10 through a plurality of solder balls 26. The plurality of solder balls 26 may be described as being included in the first package 10 and/or the second package 20.

The first package 10 may include first circuitry (e.g., first integrated circuitry or circuit (IC), also commonly referred to as a semiconductor device, a chip, a die, etc.). For example, the first circuitry of the first package 10 may include processing circuitry. Such processing circuitry (as well as any other “circuitry” disclosed herein) may include any combination of active devices (e.g., transistors, diodes, amplifiers, etc.), passive devices (e.g., resistors, capacitors, inductors, etc.), and/or electrically conductive interconnections. For example, the first package 10 may include at least a portion of the processor 120 of FIG. 1.

The second package 20 may include second circuitry (e.g., second IC). For example, the second circuitry of the second package 20 may include first memory circuitry. For example, the first memory circuitry of the second package 20 may include volatile memory, such as dynamic random-access memory (DRAM). For example, the first memory circuitry of the second package 20 may include at least a portion of the memory 130 of FIG. 1. For example, the first memory circuitry of the second package 20 may include at least a portion of the volatile memory 132 of FIG. 1.

The first package 10 and the second package 20 may be operatively and/or electrically connected to each other. For example, the first circuitry of the first package 10 may be electrically connected to the second circuitry of the second package 20 through the plurality of solder balls 26.

Referring to FIG. 3, the third package 30 may include third circuitry (e.g., third IC). For example, the third circuitry of the third package 30 may include second memory circuitry. For example, the second memory circuitry of the third package 30 may include non-volatile memory, such as a universal flash storage (UFS). For example, the second memory circuitry of the third package 30 may include at least another portion of the memory 130 of FIG. 1. For example, the second memory circuitry of the third package 30 may include at least a portion of the non-volatile memory 134 of FIG. 1. For example, the second memory circuitry of the third package 30 may include at least a portion of the internal memory 136 of FIG. 1. The third package 30 may be operatively and/or electrically connected to the first package 10.

Referring to FIG. 4, the first package 10 may include a first portion 11, a second portion 12, and a third portion 13. The first portion 11 may be disposed between the second portion 12 and the third portion 13. For example, the second portion 12 may be opposite to the third portion 13 based on the first portion 11. For example, the first portion 11 may extend from the second portion 12 to the third portion 13. For example, the first portion 11 may extend from the second portion 12 to the third portion 13 in a direction (e.g., a direction opposite to the second direction D2). The first portion 11 may be described as a central portion of the first package 10, the second portion 12 may be described as a first lateral portion of the first package 10, and the third portion 13 may be described as a second lateral portion of the first package 10.

The second package 20 may be disposed on the first portion 11 of the first package 10. For example, the second package 20 may be disposed on the first portion 11 of the portions 11, 12, and 13 of the first package 10. For example, the second package 20 may overlap (e.g., in the third direction D3) the first portion 11 of the first package 10 and may not overlap the second portion 12 and the third portion 13 of the first package 10. For example, the second portion 12 and the third portion 13 of the first package 10 may not be covered by the second package 20. For example, the first portion 11 of the first package 10 may extend (e.g., in the second direction D2) from the first portion 11 so as to protrude from the second package 20 when viewed from above (e.g., when viewed in the opposite direction of the third direction D3). For example, the second portion 12 of the first package 10 may extend (in a direction opposite to the second direction D2) from the first portion 11 so as to protrude from the second package 20 when viewed from above (e.g., when viewed in the opposite direction of the third direction D3). The plurality of solder balls 26 may electrically and mechanically connect the first package 10 and the second package 20 by being disposed between the first portion 11 of the first package 10 and the second package 20.

In FIGS. 3 and 4, the first package 10 is illustrated to have a length along the first direction D1 that is substantially the same as that of the second package 20, but is not limited thereto. For example, the first package 10 may have a length along the first direction D1 that is longer than that of the second package 20. In this case, the first package 10 may further include portions not covered by the second package 20. For example, in a case that the length of the first package 10 in the first direction D1 and a length of the first package 10 in the second direction D2 are greater than a length of the second package 20 in first direction D1 and a length of the second package 20 in the direction D2, the entire periphery portion of the first package 10 may not be covered by the second package 20.

The electronic device may further include a non-conductive material 40 disposed between the first package 10 and the second package 20. For example, the non-conductive material 40 may be disposed in at least a portion of a space between the first portion 11 of the first package 10 and the second package 20 to surround at least a portion of the plurality of solder balls 26.

The non-conductive material 40 may include epoxy, silicon, polyurethane, acrylic, polyimide, or resin including a combination thereof, but is not limited thereto.

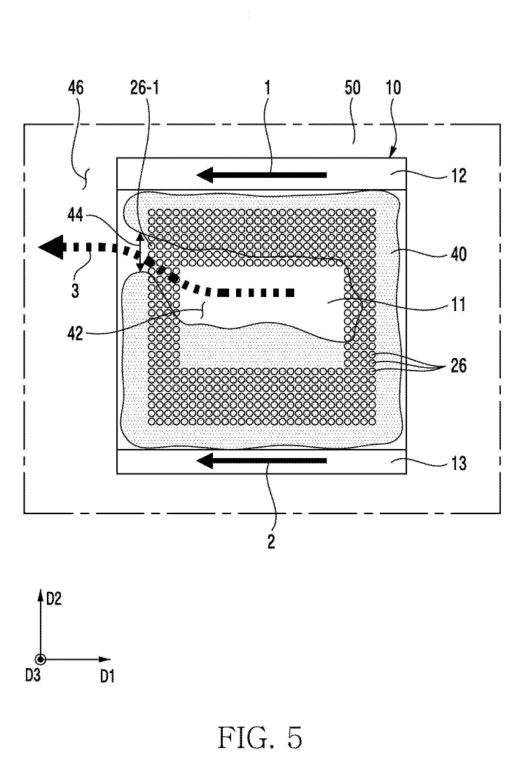

FIG. 5 is a plan view indicating a first package disposed on a printed circuit board and a non-conductive material applied to the first package.

Referring to FIG. 5, the non-conductive material 40 may be disposed on a partial region of the first portion 10 of the first package 10 so that an air path 42 open to ambient air 46 of the first package 10 (and/or the second package 20) is formed. For example, the non-conductive material 40 may include therein or define the air path 42 by extending along a portion of a periphery of the first portion 11 of the first package 10 (or a portion of a periphery of the second package 20 disposed on the first portion 11). The air pass (42) may include an outlet (44) fluidly connected to the surrounding air (46).The air path 42 may include an outlet 44 that is in communication with (e.g., open or exposed to) an ambient environment that surrounds the first package 10 and/or the second package 20. For example, the ambient environment may include the ambient air 46 of the first package 10 (and/or the second package 20). For example, the ambient air 46 may be a volume of air which surrounds the first package 10 and/or the second package 20. However, the ambient environment need not be the ambient air 46 at all, and may include any other one or more gases or environments, including an ambient environment where no gases are present (e.g., a vacuum). The outlet 44 of the air path 42 may be closer to the second portion 12 than the third portion 13 of the first package 10. For example, the non-conductive material 40 may be applied on the first package 10 along a first path 1 and a second path 2. For example, the first path 1 may extend along a first periphery of the first portion 11 adjacent to the second portion 12, and the second path 2 may extend along a second periphery of the first portion 11 adjacent to the third portion 13. At this time, the air path 42 of the non-conductive material 40 having the outlet 44 closer to the second portion 12 than the third portion 13 may be formed by making an application amount of the non-conductive material 40 along the first path 1 less than an application amount of the non-conductive material 40 along the second path 2.

The air path 42 may provide a path through which heat applied in a process (e.g., a surface mount technology (SMT) process) performed after the application of the non-conductive material 40 is released. For example, after (or before) disposing the second package 20 on the first package 10, a process of combining the first package 10 and the second package 20 may be performed while applying the non-conductive material 40 on the first package 10 and forming a plurality of solder balls 26 under a high-temperature condition. The non-conductive material 40 may thermally expand by heat applied during this process. Thermal expansion of the non-conductive material 40 may cause damage (e.g., a crack) (e.g., deviation of a solder ball) to the first package 10, the second package 20, and the plurality of solder balls 26. The air path 42 of the non-conductive material 40 may dissipate heat, thereby reducing and/or preventing the thermal expansion of the non-conductive material 40 and thus the damage to the first package 10, the second package 20, and the plurality of solder balls 26.

The portion of the plurality of solder balls 26 may be covered by the non-conductive material 40, and the remaining portion of the plurality of solder balls 26, such as the solder ball 26-1, may not be covered by the non-conductive material 40.

Referring to FIG. 4, the printed circuit board 50 on which the first package 10 and the second package 20 are disposed may be disposed in a housing (e.g., a housing 210) of the electronic device. An impact may be applied to the housing of the electronic device, and this impact may be transmitted to the first package 10, the second package 20, and the printed circuit board 50. In particular, not only the first package 10 and the second package 20 but also the plurality of solder balls 26 between the first package 10 and the second package 20 may be damaged by this external impact. Referring to FIG. 5, a portion of the plurality of solder balls 26 wrapped by the non-conductive material 40 may be protected from this external impact. However, the remaining portion of the plurality of solder balls 26 not covered by the non-conductive material 40 may be more vulnerable to this external impact. For example, the solder balls positioned in the air path 42, such as the solder ball 26-1, may be more vulnerable to such external impact.

Hereinafter, a heat transfer structure (or a heat dissipation structure) of the first package 10 and the second package 20 is described to reduce and/or prevent damage to the first package 10, the second package 20, and the plurality of solder balls 26 due to this external impact.

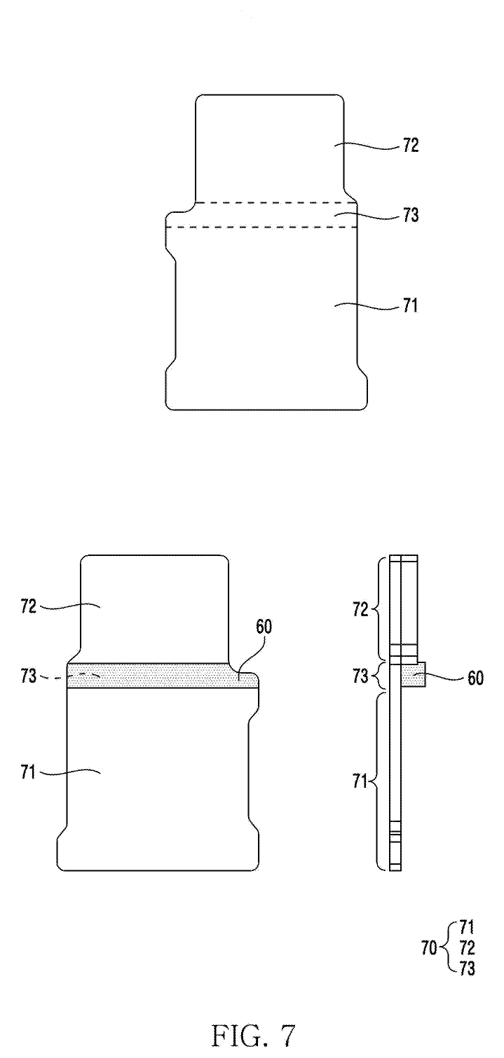

FIG. 6 is a cross-sectional view indicating a heat transfer structure (or a heat dissipation structure) of an electronic device. FIG. 7 is a plan view, a back surface view, and a side view indicating a first thermal interface material (TIM) and a second TIM.

Referring to FIG. 6, according to an embodiment, the electronic device may include a first TIM 60, a second TIM 70, a first sheet 80, a bracket 90, a display 92, a waterproof member 96, and a second sheet 94. The display 92 may be the display 201 of FIG. 2B or at least partially include the display 201 of FIG. 2B. The bracket 90 may be the frame structure 240 of FIG. 2B, or at least partially include the frame structure 240 of FIG. 2B. For example, the bracket 90 may be the second part 243 of the frame structure 240 of FIG. 2B or at least partially include the second part 243 of the frame structure 240 of FIG. 2B.

The electronic device may further include an insulating member 98 disposed (e.g., in a third direction D3) between the bracket 90 and the display 92, and disposed (e.g., in a second direction D2) between the waterproof member 96 and the second sheet 94. For example, the insulating member 98 may be formed of polyimide. The insulating member 98 may surround at least a portion of a periphery of the second sheet 94 in a plan view. The insulating member 98 may protect the periphery of the second sheet 94. As a non-limiting example, the insulating member 98 may reduce and/or prevent short between ambient circuitry or a metal component and the second sheet 94 (e.g., in a case that the second sheet 94 is formed of a material having electrical conductivity such as graphite). It is possible to reduce a height difference of a surface on which the display 92 is disposed. As a non-limiting example, the insulating member 98 may have a lower thermal conductivity than the second sheet 94. As a non-limiting example, the insulating member 98 may reduce heat transmitted from the second sheet 94 to the waterproof member 98.

The first TIM 60 and/or the second TIM 70 may include a phase change material (PCM), a matrix, and/or a thermal conductive powder, but is not limited thereto. For example, the phase change material may include paraffin, salt hydrate, and/or polylactic acid (PLA)-based composites, but is not limited thereto. For example, the matrix may include an elastic material such as rubber. For example, the thermal conductive powder may include aluminum oxide (Al2O3), but is not limited thereto. The first TIM 60 may be formed of substantially the same material as the second TIM 70. In this case, a composition ratio of materials contained in the first TIM 60 may differ from a composition ratio of materials contained in the second TIM 70 (e.g., to provide a difference in compression force between the first TIM 60 and the second TIM 70 to be described later). For another example, a portion or all of the first TIM 60 and the second TIM 70 may be formed of different materials (e.g., to provide a difference in compression force between the first TIM 60 and the second TIM 70 to be described later).

The first TIM 60 may have thermal conductivity different from that of the second TIM 70. As a non-limiting example, the first TIM 60 may have higher thermal conductivity than the second TIM 70. As a non-limiting example, thermal conductivity of the first TIM 60 may be approximately 6.0 W/(m·K). As a non-limiting example, the thermal conductivity of the first TIM 60 may be approximately 5.4 W/(m·K) to approximately 6.6 W/(m·K). As a non-limiting example, thermal conductivity of the second TIM 70 may be approximately 5 W/(m·K). As a non-limiting example, the thermal conductivity of the second TIM 70 may be approximately 4.4 W/(m·K) to approximately 5.6 W/(m·K).

Referring to FIGS. 6 and 7, the second TIM 70 may include a first portion 71, a second portion 72, and a third portion 73. The second portion 72 of the second TIM 70 may be spaced apart from the first portion 71. The third portion 73 of the second TIM 70 may be disposed between the first portion 71 and the second portion 72. The third portion 73 of the second TIM 70 may extend from the first portion 71 to the second portion 72. The portions 71, 72, and 73 of the second TIM 70 may be integrally formed. The third portion 73 of the second TIM 70 may be disposed on the first TIM 60. For example, the first TIM 60 may be attached (e.g., adhesively) to the third portion 73 of the second TIM 70.

Referring to FIG. 6, a third package 30 may be disposed around a first package 10. For example, the third package 30 may be spaced apart from the first package 10 (e.g., in the second direction D2) through a gap g.

The first TIM 60 may be disposed on a second portion 12 of the first package 10. The first TIM 60 may support the second TIM 70 disposed thereon. The first TIM 60 disposed on the second portion 12 of the first package 10 may be adjacent to a side surface (and/or the non-conductive material 40 between the first package 10 and the second package 20) of the second package 20. For example, the first TIM 60 disposed on the second portion 12 of the first package 10 may be in contact with a side surface (and/or the non-conductive material 40 between the first package 10 and the second package 20) of the second package 20. The first TIM 60 may be thermally connected to the first package 10 and the second package 20 (e.g., through physical contact with the second portion 12 of the first package 10 and the side surface of the second package 20). Additionally, the first TIM 60 may also be thermally connected to the third package 30. For example, the first TIM 60 may further include a portion in contact with the third package 30 (e.g., the side surface of the third package 30 facing the first package 10) for thermal connection with the third package 30. In the present disclosure, thermal connection between A and B may include not only directly thermally connected to A and B, but also indirectly thermally connected through one or more other members. In addition, in the present disclosure, contact (e.g., physical contact) between A and B may include not only direct contact between A and B, but also indirect contact through one or more other members.

The second TIM 70 may be disposed on the second package 20 and the first TIM 60. The second TIM 70 may be further disposed on the third package 30 (i.e., the second TIM 70 may further include the second portion 72). The second TIM 70 may be thermally connected to the second package 20, the first TIM 60, and the third package 30.

The first portion 71 of the second TIM 70 may be disposed on the second package 20. The first portion 71 of the second TIM 70 may be thermally connected to the second package 20. For example, the first portion 71 of the second TIM 70 may be thermally connected to the second package 20 through physical contact with a top surface of the second package 20.

The second portion 72 of the second TIM 70 may be disposed on the third package 30. The second portion 72 of the second TIM 70 may be thermally connected to the third package 30. For example, the second portion 72 of the second TIM 70 may be thermally connected to the third package 30 through physical contact with a top surface of the third package 30.

The third portion 73 of the second TIM 70 may extend from the first portion 71 to the second portion 72 across the first TIM 60. The third portion 73 of the second TIM 70 may be thermally connected to the first TIM 60. For example, the third portion 73 of the second TIM 70 may be thermally connected to the first TIM 60 through physical contact with the first TIM 60 (or through attachment with the first TIM 60).

A thickness (e.g., a thickness along the third direction D3) of the first portion 71 of the second TIM 70 may be substantially the same as a thickness (e.g., a thickness along the third direction D3) of the third portion 73, but is not limited thereto. For example, the thickness of the third portion 73 of the second TIM 70 may be thicker than the thickness of the first portion 71 (e.g., in a case that a thickness of the first TIM 60 becomes thinner than an illustrated example).

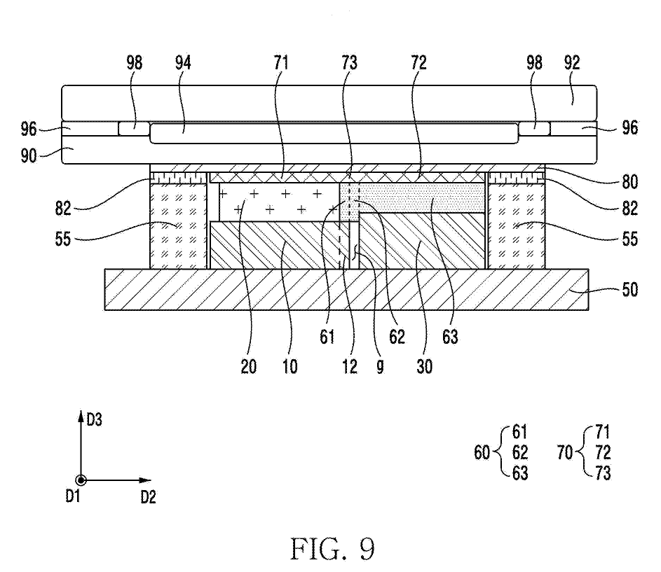

A thickness (e.g., a thickness along the third direction D3) of the second portion 72 of the second TIM 70 may be thicker than thicknesses of the first portion 71 and/or the third portion 73, but is not limited thereto. For example, the thickness of the second portion 72 of the second TIM 70 may vary according to a height of the third package 30. For another example, the first TIM 60 may be further expanded so as to be interposed between the second portion 72 of the second TIM 70 and the third package 30 (e.g., FIG. 9). In this case, the thickness of the second portion 72 of the second TIM 70 may be thinner than an illustrated example. For example, the second portion 72 of the second TIM 70 may have substantially the same thickness as the first portion 71 and/or the third portion 73.

The thickness of the first TIM 60 (e.g., the thickness along the third direction D3) may be substantially the same as a thickness (e.g., a height from a top surface of the first package 10 to the top surface of the second package 20 along the third direction D3) of the second package 20, but is not limited thereto. For example, the thickness of the first TIM 60 may be less than the thickness of the second package 20 (e.g., in a case that the third portion 73 of the second TIM 70 is recessed from the first portion 71 and the second portion 72 in the third direction D3) (e.g., in a case that the third portion 73 of the second TIM 70 protrudes from the first portion 71 in the opposite direction to the third direction D3 and is recessed from the second portion 72 in the third direction D3). For another example, the first TIM 60 may further include a portion having a thickness greater than the thickness of the second package 20 (e.g., in a case that the first TIM 60 further extends to at least a portion of the gap g).

The first TIM 60 disposed on the second portion 12 of the first package 10 may be closer to a printed circuit board 50 than the second portion 72 of the second TIM 70, but is not limited thereto. For example, in a case that the height of the third package 30 is formed substantially the same as that of the first package 10, a distance between the first TIM 60 and the printed circuit board 50 may be substantially the same as the distance between the second portion 72 of the second TIM 70 and the printed circuit board 50.

The first sheet 80 may be configured to shield electromagnetic waves. In addition, the first sheet 80 may be configured to transmit heat (or radiate heat). For example, the first sheet 80 may include a conductive material and a heat transfer material (or TIM). For example, the first sheet 80 may include a composite material including conductive metal, carbon fiber, carbon black, carbon nanotube (CNT), nickel coated graphite, and/or a combination thereof as the conductive material, but is not limited thereto. For example, the first sheet 80 may include an electrically conductive material and/or a first layer including the same. For example, the first sheet 80 may include a heat radiating filler filled with the graphite and/or a binder as the heat transfer material, but is not limited thereto.

The first sheet 80 may be disposed on a shield can 55 to cover a top opening (e.g., a top opening 57) of the shield can 55. For example, the first sheet 80 may be attached to the shield can 55 through an adhesive member 82. For example, the first sheet 80 may include a first region covering the top opening of the shield can 55 and a second region surrounding the first region and attached to the shield can 55 through the adhesive member 82. The adhesive member 82 may include a conductive adhesive material to electrically connect the first sheet 80 and the shield can 55. Alternatively, the first sheet 80 may be replaced with the top wall of the shield can 55 (e.g., in a case that the top opening 55 of the shield can 55 is omitted).

The second TIM 70 may be disposed under the first sheet 80. For example, the second TIM 70 may be attached to a back surface of the first sheet 80 facing an inside of the shield can 55 (or the printed circuit board 50). For example, the second TIM 70 may be attached to the second region (or its back surface) of the first sheet 80. For example, the second TIM 70 may be coupled to the first sheet 80. As a non-limiting example, the second TIM 70 may be coupled by at least partially penetrating into the first sheet 80. Accordingly, the first sheet 80 may be thermally connected to the second TIM 70.

The bracket 90 may be disposed between the display 92 and the first sheet 80. The first sheet 80 may be disposed on a first surface of bracket 90. The first sheet 80 may be thermally connected to the bracket 90 by contacting at least a portion of the bracket 90. At least a portion of the display 92 may be seated on a second surface opposite to the first surface of the bracket 90. For example, a periphery portion of the display 92 may be attached to the second surface of the bracket 90 through the waterproof member 96. The waterproof member 96 may include a waterproof adhesive material. The waterproof member 96 may surround the second sheet 94. The second sheet 94 may be disposed between the display 92 and the bracket 90. The bracket 90 may be thermally connected to the second sheet 94 disposed on the second surface of the bracket 90. In addition, the second sheet 94 may be thermally connected to the display 92 by contacting at least a portion of the display 92. The second sheet 94 may be formed of the heat transfer material such as the graphite. In this case, the second sheet 94 may be referred to as a graphite sheet.

Heat generated from the first package 10 and the second package 20 may be transmitted to the first TIM 60 and the second TIM 70. In addition, heat generated from the third package 30 may be transmitted to the first TIM 60 and the second TIM 70. The heat transmitted to the first TIM 60 may be transmitted to the second TIM 70.

The electronic device may include a heat dissipation member (or a heat sink) (or a heat transfer member) thermally connected to the second TIM 70. For example, the heat dissipation member may include at least one of the first sheet 80, the bracket 90, the second sheet 94, and/or the display 92.

For example, the heat dissipation member may include the first sheet 80. For example, the heat transmitted to the second TIM 70 may be transmitted to the first sheet 80. Accordingly, overheating of the packages 10, 20, and 30 may be reduced and/or prevented. For example, the heat dissipation member may further include the bracket 90. The heat transmitted to the first sheet 80 may be transmitted to the bracket 90. The bracket 90 may dissipate heat to an outside and/or transmit the heat to the second sheet 94. Accordingly, the heat generated from the packages 10, 20, and 30 may be diffused and/or dissipated, and overheating of the packages 10, 20, and 30 may be reduced and/or prevented. The heat dissipation member may further include the second sheet 94. Heat transmitted to the bracket 90 may be diffused as it is transmitted to the second sheet 94. The heat dissipation member may further include the display 92. Heat transmitted to the second sheet 94 may be diffused and/or dissipated to the outside as it is transmitted to the display 92.

Meanwhile, an impact may be applied from the outside of the electronic device. For example, such impact may be transmitted to the first package 10 and the second package 20 disposed inside the electronic device. In this case, the first package 10, the second package 20, and a plurality of solder balls (e.g., a plurality of solder balls 26) interconnecting them may be damaged.

In order to reduce and/or prevent the above-described problem, the first TIM 60 may have greater compression force than the second TIM 70. The compression force may be defined as force (or pressure) required to compress at a certain temperature (e.g., 25 degrees Celsius) to a specified compression rate (e.g., 20%). As a non-limiting example, compression force of the first TIM 60 may be approximately 1.5 kgf/cm² (e.g., may be a maximum value) under a compression ratio condition of 25 degrees Celsius and 20%. As a non-limiting example, compression force of the second TIM 70 may be approximately 1.0 kgf/cm² (e.g., may be a maximum value) under the same condition. As a non-limiting example, compressive force of the second TIM 70 may be approximately 0.7 kgf/cm² (e.g., may be a maximum value) under the same condition. As a non-limiting example, compression force of the second TIM 70 may be approximately 0.4 kgf/cm² to approximately 1.0 kgf/cm² under the same condition.

For example, the first TIM 60 may have resilience greater than that of the second TIM 70. In the field of material science, “resilience” may refer to the ability of a material to absorb energy when it is deformed elastically, and release that energy upon unloading, generally by reverting to the material’s original shape before deformation. The resilience of a material may be referred to as its modulus of resilience is defined as the maximum energy that can be absorbed per unit volume without creating a permanent distortion and can be calculated by integrating the stress–strain curve from zero to the elastic limit. For example, the first TIM 60 may have a repulsive force greater than that of the second TIM 70. In material science, “repulsive force” (also known as “tensile strength”) may refer to the maximum stress that a material can withstand while being stretched or pulled before breaking. The repulsive force and may be measured in units of force per unit area (i.e., units of pressure). For example, the first TIM 60 may have a stiffness (or a compressive stiffness) greater than that of the second TIM 70. A material’s stiffness (also commonly referred to as a material’s “hardness” or “rigidity”) may be quantified by calculating an elastic modulus specific to that material, such as the material’s Young’s modulus. The Young's modulus is a mechanical property of solid materials that measures the tensile or compressive stiffness when a force is applied lengthwise thereto. The Young’s modulus is the elastic modulus for tension or axial compression. The Young’s modulus is defined as the quotient of the stress (force per unit area) applied to the material and the resulting axial strain (a dimensionless quantity that quantifies relative deformation) in the linear elastic region of the material. For example, the first TIM 60 may have a compression resistance greater than that of the second TIM 70. In material science, “compression resistance” (also known as “compression strength” or “compressive strength”) may refer to the capacity of a material or structure to withstand loads tending to reduce size (compression) and may be measured in units of force per unit area (i.e., units of pressure). For example, the first TIM 60 may have the resilience, the repulsive force, the stiffness, and/or the compression resistance greater than those of the second TIM 70. For example, the first TIM 60 may be harder than the second TIM 70. Damage to the first package 10 and the second package 20 may be reduced and/or prevented, since at least a portion of an impact applied from the outside is transmitted to the first package 10 and the second package 20 through the second TIM 70 and the first TIM 60 having the compression force greater than that of the second TIM 70. For example, the first TIM 60 disposed under the second TIM 70 may structurally support the second TIM 70. When the external impact is applied, a load applied to the first package 10 and the second package 20 may be distributed without being locally concentrated since the first TIM 60 acts as a structural support, and the second TIM 70 distributes and/or buffers the impact. Accordingly, damage to the first package 10 and the second package 20 due to the external impact may be reduced and/or prevented.

For example, the first TIM 60 may be omitted, or the first TIM 60 may be replaced with the second TIM 70 having compression force lower than this. In this case, a crack occurred in the second package 20, when a sphere with a diameter of 17.6 mm and a weight of 21.7 g was freely dropped from a height of 40 cm. In contrast, the crack of the second package 20 did not occur under the same condition, and even though the height of a free fall was increased to 50 cm, the crack of the second package 20 did not occur in case that the first TIM 60 and the second TIM 70 are included.

In a comparative example, the compression force of the second TIM 70 may be improved to a level similar to or equivalent to that of the first TIM 60. However, in order to implement such a compression force, a larger thickness of the second TIM 70 may be required. In this case, the total thickness of the electronic device may be increased. In an embodiment, the first portion 71 of the second TIM 70 disposed between the second package 20 and the first sheet 80 may be thinner than the first TIM 60 disposed between the second portion 12 of the first package 10 and the third portion 73 of the second TIM 70. In other words, an increase in a thickness may be reduced and/or prevented by disposing the second TIM 70 between the second package 20 and the first sheet 80, and durability of the packages 10 and 20 may be improved while reducing a thickness of the electronic device by disposing the first TIM 60 with relatively high compression force and a thick thickness between the second portion 12 of the first package 10 and the third portion 73 of the second TIM 70.

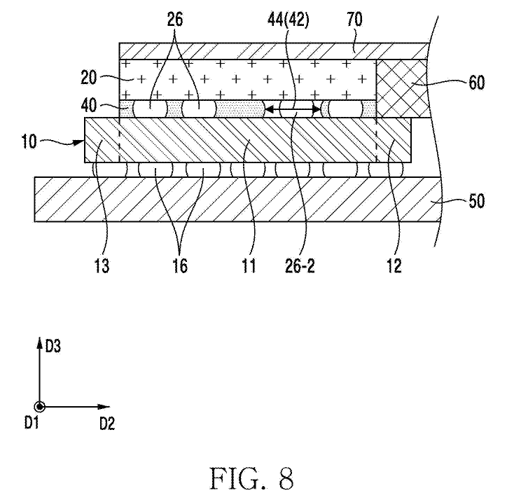

FIG. 8 is a side view indicating packages and TIMs.

Referring to FIG. 8, a plurality of solder balls 26 may include a solder ball 26-2 (e.g., a solder ball 26-1). The solder ball 26-2 may be positioned in an air path 42 formed by a non-conductive material 40. The solder ball 26-2 may be closest to an outlet 44 of the air path 42 among the plurality of solder balls 26. For example, the plurality of solder balls 26 may include first solder balls surrounded by the non-conductive material 40 and second solder balls disposed in the air path 42 not covered by the non-conductive material 40. The solder ball 26-2 may be closest to the outlet 44 of the air path 42 among the second solder balls.

The solder ball 26-2 may be closer to a second portion 12 of a first package 10 on which a first TIM 60 is disposed than a third portion 13 of the first package 10. Damage due to the above-described external impact may be further intensified in a case that the solder ball 26-2 is not protected by the non-conductive material 40. Damage to a solder ball not protected by the non-conductive material 40 by the above-described external impact may be reduced and/or prevented by disposing the first TIM 60 closer to the solder ball not wrapped by the non-conductive material 40, such as the solder ball 26-2.

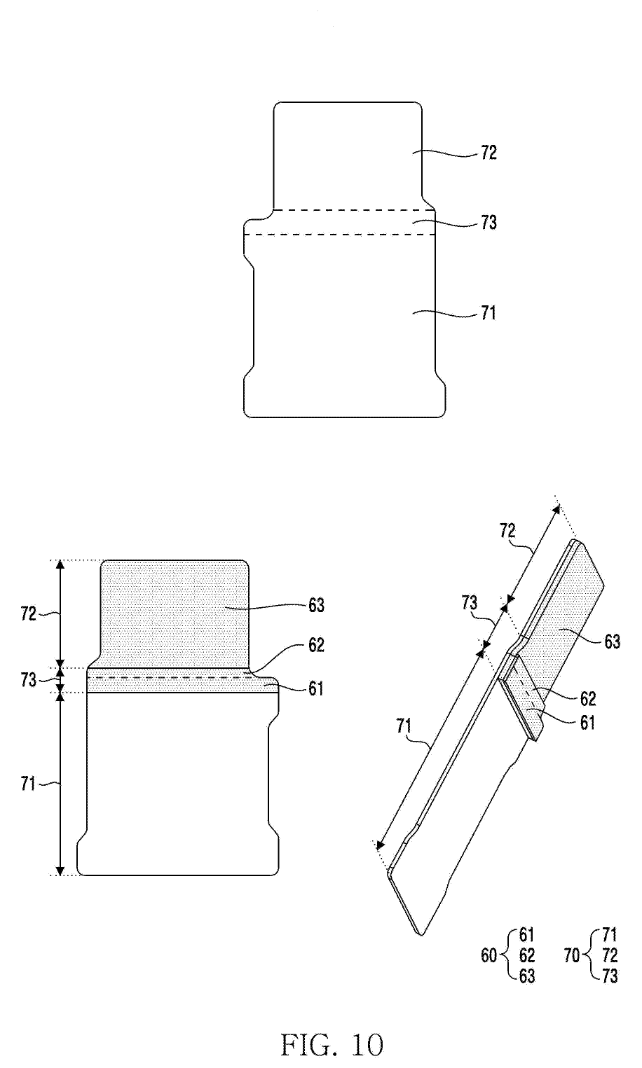

FIG. 9 is a cross-sectional view indicating a heat transfer structure (or a heat dissipation structure) of an electronic device. FIG. 10 is a plan view, a back surface view, and a side view indicating a first TIM and a second TIM.

Referring to FIGS. 9 and 10, a first TIM 60 may include a first portion 61, a second portion 62, and a third portion 63. The portions 61, 62, and 63 of the first TIM 60 may be integrally formed.

The first portion 61 and the second portion 62 of the first TIM 60 may be substantially the same as the first TIM 60 illustrated in FIG. 6. That is, the first TIM 60 illustrated in FIG. 9 may further include the third portion 63 compared to the first TIM 60 of FIG. 6. The third portion 63 of the first TIM 60 illustrated in FIG. 9 may replace a portion of the second portion 72 of the second TIM 70 illustrated in FIG. 6. For example, the third portion 63 of the first TIM 60 illustrated in FIG. 9 may be disposed between the remaining portion of the second portion 72 of the second TIM 70 and a third package 30 to replace a portion of the second portion 72 of the second TIM 70 illustrated in FIG. 6.

For example, referring to FIG. 9, the first portion 61 of the first TIM 60 may be disposed on a second portion 12 of a first package 10. The third portion 63 of the first TIM 60 may be disposed on the third package 30. The second portion 62 of the first TIM 60 may extend across a gap g between the first package 10 and the second package 20 from the first portion 61 of the first TIM 60 to the third portion 63 of the first TIM 60.

For example, the first portion 61 and/or the second portion 62 of the first TIM 60 may protrude toward a printed circuit board 50 rather than the third portion 63 of the first TIM 60. Unlike illustration, the second portion 62 of the first TIM 60 may protrude toward the printed circuit board 50 (or into the gap g) rather than the first portion 61 of the first TIM 60.

For example, a third portion 73 of the second TIM 70 may be disposed on the first portion 61 and the second portion 62 of the first TIM 60. The second portion 72 of the second TIM 70 may be disposed on the third portion 63 of the first TIM 60. The second portion 72 of the second TIM 70 may have substantially the same thickness as the first portion 71 and the third portion 73.

The first TIM 60 may have compression force greater than that of the second TIM 70. Damage to the first package 10, the second package 20, and the third package 30 may be reduced and/or prevented since at least a portion of an external impact is transmitted to the first package 10, the second package 20, and the third package 30 through the second TIM 70 and the first TIM 60 having the compression force greater than that of the second TIM 70.

A technical task to be achieved from the present disclosure is not limited to those described above, and any other technical tasks not mentioned herein will be clearly understood by those having ordinary knowledge in the art to which the present disclosure belongs.

The above-described electronic device 200 may comprise a printed circuit board 50, a first package 10 including first circuitry and disposed on the printed circuit board 50, and a second package 20 including second circuitry and disposed on the first package 10. The first package 10 may include a first portion 11 on which the second package 20 is disposed and a second portion 12 not covered by the second package 20. The electronic device 200 may comprise a first thermal interface material (TIM) 60 disposed on the second portion 12 of the first package 10, a second TIM 70 disposed on the second package 20 and the first TIM 60, and a heat dissipation member thermally connected to the first package 10 and the second package 20 through the first TIM 60 and the second TIM 70. The first TIM 60 may have a stiffness greater than that of the second TIM 70.

The second package 20 may include a plurality of solder balls 26, disposed on the first portion 11 of the first package 10, electrically connecting the first circuitry of the first package 10 and the second circuitry of the second package 20. The electronic device 200 may include a non-conductive material 40 disposed between the first package 10 and the second package 20 to surround at least some of the plurality of solder balls 26. The first TIM 60 may be disposed adjacent to the non-conductive material 40.

The first package 10 may include a third portion 13 opposite to the second portion 12 of the first package 10 and not covered by the second package 20. The non-conductive material 40 may define an air path 42 open to ambient air 46 of the first and second packages 10, and 20. The plurality of solder balls 26 may include a first solder ball 26-1 or 26-2 not covered by the non-conductive material 40 and being closest to an outlet 44 of the air path 42 that is in communication with the ambient air. The first solder ball 26-1 or 26-2 may be closer to the second portion 12 of the first package 10 on which the first TIM 60 is disposed than the third portion 13 of the first package 10.

The electronic device 200 may comprise a third package 30 including third circuitry and disposed on the printed circuit board 50. The second TIM 70 may include a first portion 71 disposed on the second package 20, a second portion 72 disposed on the third package 30, and a third portion 73 disposed on the first TIM 60 and extending from the first portion 71 of the second TIM 70 to the second portion 72 of the second TIM 70.

The first portion 71 of the second TIM 70 may have a thickness thinner than that of the first TIM 60.

The electronic device 200 may comprise a third package 30 including third circuitry and disposed on the printed circuit board 50. The first TIM 60 may include a first portion 61 disposed on the second portion 12 of the first package 10, a second portion 63 disposed on the third package 30, and a third portion 63 extending from the first portion 61 of the first TIM 60 to the second portion 63 of the first TIM 60 across a gap g between the first package 10 and the third package 30.

The third portion 62 of the first TIM 60 may protrude from the second portion 63 of the first TIM 60 toward the printed circuit board 50.

The second TIM 70 may include a first region overlapping the second package 20 in a thickness direction of the printed circuit board 50, and a second region overlapping the first, second, and third portions 61, 63, and 62 of the first TIM 60 in the thickness direction of the printed circuit board 50.

The electronic device 200 may comprise a third package 30 including third circuitry and disposed on the printed circuit board 50. The first TIM 60 may include a first portion 61 disposed on the second portion 12 of the first package 10, and a second portion 62, spaced apart from the second portion 12 of the first package 10, extending from the first portion 61 of the first TIM 60 toward the third package 30.

The first circuitry of the first package 10 may include processing circuitry. The second circuitry of the second package 20 may include first memory circuitry. The third circuitry of the third package 30 may include second memory circuitry.

The electronic device 200 may comprise a shielding sheet 80. The second TIM 70 may be attached to the shielding sheet 80. The first TIM 60 may be attached to the second TIM 70.

The electronic device 200 may comprise a shield can 55 including a side wall disposed on the printed circuit board 50 to surround the first package 10 and the second package 20 and a top wall extending from the side wall, the top wall defining an opening 57. The shielding sheet 80 may be attached to the top wall of the shield can 55 to cover the opening 57 of the shield can 55.

The shielding sheet 80 may include a first region to which the second TIM 70 is attached, and a second region surrounding the first region and attached to the shield can 55.

The heat dissipation member may be thermally connected to the first package 10 and the second package 20 through the shielding sheet 80, the first TIM 60, and the second TIM 70.

The heat dissipation member may include a bracket 90 disposed on the shielding sheet 80.

The above-described electronic device 200 may comprise a printed circuit board 50, a first package 10 including first circuitry and disposed on the printed circuit board 50, and a second package 20 including second circuitry and disposed on the first package 10. The first package 10 may include a first portion 11 on which the second package 20 is disposed and a second portion 12 not covered by the second package 20. The electronic device 200 may comprise a shield can 55 disposed on the printed circuit board 50 to enclose the first and second packages 10, and 20 and having an opening 57 formed at a top wall thereof corresponding the second package 20, a shielding sheet 80 disposed on the shield can 55 to cover the opening 57, a first thermal interface material (TIM) 60 disposed on the second portion 12 of the first package 10 and thermally connected with the first package 10, a second TIM 70 disposed on the second package 20 and the first TIM 60 and under the shielding sheet 80, the second TIM 70 thermally connected with the first TIM 60, the second package 20, and the shielding sheet 80, and a heat dissipation member disposed on the shielding sheet 80 and thermally connected to the shielding sheet 80. The first TIM 60 may have a stiffness greater than that of the second TIM 70.

The second package 20 may include a plurality of solder balls 26, disposed on the first portion 11 of the first package 10, electrically connecting the first circuitry of the first package 10 and the second circuitry of the second package 20. The electronic device 200 may include a non-conductive material 40 disposed between the first package 10 and the second package 20 to surround at least some of the plurality of solder balls 26. The first TIM 60 may be disposed adjacent to the non-conductive material 40.

The first package 10 may include a third portion 13 opposite to the second portion 12 of the first package 10 and not covered by the second package 20. The non-conductive material 40 may define an air path 42 open to ambient air 46 of the first and second packages 10, and 20. The plurality of solder balls 26 may include a first solder ball 26-1 or 26-2 not covered by the non-conductive material 40 and being closest to an outlet 44 of the air path 42 that is in communication with the ambient air. The first solder ball 26-1 or 26-2 may be closer to the second portion 12 of the first package 10 on which the first TIM 60 is disposed than the third portion 13 of the first package 10.

The electronic device 200 may comprise a third package 30 including third circuitry and disposed on the printed circuit board 50. The second TIM 70 may include a first portion 71 disposed on the second package 20, a second portion 72 disposed on the third package 30, and a third portion 73 disposed on the first TIM 60 and extending from the first portion 71 of the second TIM 70 to the second portion 72 of the second TIM 70. The first portion 71 of the second TIM 70 may have a thickness thinner than that of the first TIM 60.

The electronic device 200 may comprise a third package 30 including third circuitry and disposed on the printed circuit board 50. The first TIM 60 may include a first portion 61 disposed on the second portion 12 of the first package 10, a second portion 63 disposed on the third package 30, and a third portion 62 extending from the first portion 61 of the first TIM 60 to the second portion 63 of the first TIM 60 across a gap g between the first package 10 and the third package 30. The second TIM 70, which is disposed on the first TIM 60, may extend across the first, second, and third portions 61, 63, and 62 of the first TIM 60. A thickness of the second TIM 70 may be thinner than a thickness of the first portion 61 of the first TIM 60.

In one or more embodiments, the second package may include a plurality of solder balls on the first portion of the first package, the plurality of solder balls being configured to electrically connect the first circuitry of the first package to the second circuitry of the second package. The electronic device may further include a non-conductive material between the first package and the second package and around at least a portion of the plurality of solder balls, and the first TIM may be adjacent to the non-conductive material.

In one or more embodiments, the first package may further include a third portion opposite the second portion; the non-conductive material may include an air path open to an ambient environment; the plurality of solder balls may include a first solder ball exposed to the ambient environment; and the first solder ball may be closer to the second portion than the third portion.

In one or more embodiments, the electronic device may further include a third package on the printed circuit board that includes third circuitry, and the second TIM may include a first portion on the second package; a second portion on the third package; and a third portion on the first TIM and extending from the first portion of the second TIM to the second portion of the second TIM.

In one or more embodiments, the first portion of the second TIM may have a second thickness thinner than a first thickness of the first TIM.

In one or more embodiments, the electronic device may further include a third package on the printed circuit board that includes third circuitry, and the first TIM may include a first portion on the second portion of the first package; a third portion on the third package; and a second portion extending from the first portion of the first TIM to the third portion of the first TIM across a gap between the first package and the third package.

In one or more embodiments, the second portion of the first TIM may protrude from the third portion of the first TIM toward the printed circuit board.

In one or more embodiments, the second TIM may include a first region overlapping the second package in a thickness direction of the printed circuit board; and a second region overlapping the first portion of the first TIM, the second portion of the first TIM, and the third portion of the first TIM in the thickness direction of the printed circuit board.

In one or more embodiments, the electronic device may further include a third package on the printed circuit board that includes third circuitry, the first TIM may include a first portion on the second portion of the first package; and a second portion spaced apart from the second portion of the first package and extending from the first portion of the first TIM toward the third package.

In one or more embodiments, the first circuitry of the first package may include processing circuitry; the second circuitry of the second package may include first memory circuitry; and the third circuitry of the third package may include second memory circuitry.

In one or more embodiments, the electronic device may further include a shielding sheet on the second TIM and the first TIM.

In one or more embodiments, the electronic device may further include a shield can including a side wall on the printed circuit board, the side wall being disposed around the first package and the second package; and a top wall extending from the side wall and including an opening therein, and the shielding sheet may be on the top wall of the shield can and over the opening.

In one or more embodiments, the shielding sheet may include a first region on the second TIM; and a second region disposed around the first region and on the shield can.

In one or more embodiments, the heat dissipation member may be thermally connected to the first package and the second package through the shielding sheet, the first TIM, and the second TIM.

In one or more embodiments, the heat dissipation member may include a bracket on the shielding sheet.

In one or more embodiments, the second package may include a plurality of solder balls on the first portion of the first package, the plurality of solder balls may be configured to electrically connect the first circuitry of the first package to the second circuitry of the second package, wherein the electronic device includes a non-conductive material between the first package and the second package and around at least a portion of the plurality of solder balls, and wherein the first TIM is adjacent to the non-conductive material.

In one or more embodiments, the first package may include a third portion opposite to the second portion; the non-conductive material may include an air path open to an ambient environment; the plurality of solder balls may include a first solder ball exposed to the ambient environment; and the first solder ball may be closer to the second portion than the third portion.

In one or more embodiments, the electronic device may further include a third package on the printed circuit board that includes third circuitry, and the second TIM may include a first portion on the second package; a second portion on the third package; and a third portion on the first TIM and extending from the first portion of the second TIM to the second portion of the second TIM, wherein the first portion of the second TIM has a second thickness thinner than a first thickness of the first TIM.

In one or more embodiments, the electronic device may further include a third package on the printed circuit board that includes third circuitry, the first TIM may include a first portion on the second portion of the first package; a third portion on the third package; and a second portion extending from the first portion of the first TIM to the third portion of the first TIM across a gap between the first package and the third package, wherein the second TIM extends across the first portion of the first TIM, the second portion of the first TIM, and the third portion of the first TIM, and wherein a second thickness of the second TIM is thinner than a first thickness of the first portion of the first TIM.

The effects that may be obtained from the present disclosure are not limited to those described above, and any other effects not mentioned herein will be clearly understood by those having ordinary knowledge in the art to which the present disclosure belongs.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly, or “hardwired”), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer’s server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a printed circuit board;
a first package including first circuitry and disposed on the printed circuit board;
a second package including second circuitry and disposed on the first package,
wherein the first package includes a first portion on which the second package is disposed and a second portion;
a first thermal interface material (TIM) disposed on the second portion of the first package;
a second TIM disposed on the second package and the first TIM; and
a heat dissipation member thermally connected to the first package and the second package through the first TIM and the second TIM,
wherein the first TIM has a stiffness greater than that of the second TIM.

2. The electronic device of claim 1, wherein the second package comprises a plurality of solder balls, disposed on the first portion of the first package, the plurality of solder balls configured to electrically connect the first circuitry of the first package to the second circuitry of the second package,
wherein the electronic device includes a non-conductive material disposed between the first package and the second package and around at least a portion of the plurality of solder balls, and
wherein the first TIM is disposed adjacent to the non-conductive material.

3. The electronic device of claim 2, wherein:
the first package includes a third portion opposite the second portion;
the non-conductive material includes an air path open to an ambient environment;
the plurality of solder balls include a first solder ball exposed to the ambient environment; and
the first solder ball is closer to the second portion than the third portion.

4. The electronic device of claim 1, comprising a third package including third circuitry and disposed on the printed circuit board,
wherein the second TIM includes:
a first portion disposed on the second package;
a second portion disposed on the third package; and
a third portion disposed on the first TIM and extending from the first portion of the second TIM to the second portion of the second TIM.

5. The electronic device of claim 4, wherein the first portion of the second TIM has a thickness thinner than that of the first TIM.

6. The electronic device of claim 1, comprising a third package including third circuitry and disposed on the printed circuit board, and
wherein the first TIM includes:
a first portion disposed on the second portion of the first package;
a second portion disposed on the third package; and
a third portion extending from the first portion of the first TIM to the second portion of the first TIM across a gap between the first package and the third package.

7. The electronic device of claim 6,
wherein the third portion of the first TIM protrudes from the second portion of the first TIM toward the printed circuit board.

8. The electronic device of claim 6, wherein the second TIM includes:
a first region overlapping the second package in a thickness direction of the printed circuit board; and
a second region overlapping the first portion of the first TIM, the second portion of the first TIM, and the third portion of the first TIM in the thickness direction of the printed circuit board.

9. The electronic device of claim 1, comprising a third package including third circuitry and disposed on the printed circuit board,
wherein the first TIM includes:
a first portion disposed on the second portion of the first package; and
a second portion spaced apart from the second portion of the first package and extending from the first portion of the first TIM toward the third package.

10. The electronic device of claim 9, wherein:
the first circuitry of the first package includes processing circuitry;
the second circuitry of the second package includes first memory circuitry; and
the third circuitry of the third package includes second memory circuitry.

11. The electronic device of claim 1, comprising a shielding sheet on the second TIM and the first TIM.

12. The electronic device of claim 11, comprising:
a shield can including a side wall disposed on the printed circuit board and around the first package and the second package; and
a top wall extending from the side wall and including an opening therein, and
wherein the shielding sheet is on the top wall of the shield can and over the opening.

13. The electronic device of claim 12, wherein the shielding sheet comprises:
a first region on the second TIM; and
a second region around the first region and on the shield can.

14. The electronic device of claim 13,
wherein the heat dissipation member is thermally connected to the first package and the second package through the shielding sheet, the first TIM, and the second TIM.

15. The electronic device of claim 14,
wherein the heat dissipation member comprises a bracket disposed on the shielding sheet.

16. An electronic device comprising:
a printed circuit board;
a first package on the printed circuit board and comprising first circuitry;
a second package on the first package and comprising second circuitry,
wherein the first package comprises a first portion and a second portion, the second package being on the first portion;
a shield can on the printed circuit board around the first package and the second package and having an opening in a top wall thereof;
a shielding sheet on the shield can and over the opening;
a first thermal interface material (TIM) on the second portion of the first package and thermally connected to the first package;
a second TIM on the second package and the first TIM and under the shielding sheet, the second TIM being thermally connected to the first TIM, the second package, and the shielding sheet; and
a heat dissipation member on the shielding sheet and thermally connected to the shielding sheet,
wherein the first TIM has a first stiffness greater than a second stiffness of the second TIM.

17. The electronic device of claim 16,
wherein the second package includes a plurality of solder balls, disposed on the first portion of the first package, electrically connecting the first circuitry of the first package and the second circuitry of the second package,
wherein the electronic device includes a non-conductive material disposed between the first package and the second package to surround at least a portion of the plurality of solder balls, and
wherein the first TIM is disposed adjacent to the non-conductive material.

18. The electronic device of claim 17, wherein:
the first package comprises a third portion opposite to the second portion;
the non-conductive material includes an air path open to an ambient environment;
the plurality of solder balls comprise a first solder ball exposed to the ambient environment; and
the first solder ball is closer to the second portion than the third portion.

19. The electronic device of claim 16, comprising a third package including third circuitry and disposed on the printed circuit board,
wherein the second TIM includes:
a first portion disposed on the second package;
a second portion disposed on the third package; and
a third portion disposed on the first TIM and extending from the first portion of the second TIM to the second portion of the second TIM, and
wherein the first portion of the second TIM has a thickness thinner than that of the first TIM.

20. The electronic device of claim 16, comprising a third package including third circuitry and disposed on the printed circuit board, and
wherein the first TIM includes:
a first portion disposed on the second portion of the first package;
a second portion disposed on the third package; and
a third portion extending from the first portion of the first TIM to the second portion of the first TIM across a gap between the first package and the third package,
wherein the second TIM, which is disposed on the first TIM, extends across the first, second, and third portions of the first TIM, and
wherein a thickness of the second TIM is thinner than a thickness of the first portion of the first TIM.
